(19) United States
(12) Patent Application Publication
(10) Pub. No.: US 2009/0061329 A1
(43) Pub. Date: Mar. 5, 2009

(54) SEMICONDUCTOR DEVICE MANUFACTURING METHOD AND HARD MASK

(75) Inventor: Toshiyuki HIROTA, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: ELPIDA MEMORY, INC., Tokyo (JP)

(21) Appl. No.: 12/199,623

(22) Filed: Aug. 27, 2008

(30) Foreign Application Priority Data
Aug. 30, 2007 (JP) 2007-224423

(51) Int. Cl. G03F 1/00; G03F 7/20

(52) U.S. Cl. 430/5; 430/319

(57) ABSTRACT

A semiconductor device manufacturing method includes forming a target film to be processed on a semiconductor substrate in which a semiconductor element has been formed; forming a hard mask on the target film; and patterning the target film. The hard mask is a multilayer film including a conductive carbon film and a transparent carbon film which are sequentially stacked on the target film. The formation of the hard mask may include sequentially stacking the conductive carbon film and the transparent carbon film on the target film on the semiconductor substrate; sequentially stacking an intermediate layer and a resist layer on the transparent carbon film; patterning the resist layer; patterning the intermediate layer by using the patterned resist layer as a mask; and patterning the conductive carbon film and the transparent carbon film by using the patterned intermediate layer as a mask.

### BACKGROUND OF THE INVENTION

1. Field of the Invention

The present invention relates to a method of manufacturing a semiconductor device, and also to a hard mask.

Priority is claimed on Japanese Patent Application No. 2007-224423, filed Aug. 30, 2007, the contents of which are incorporated herein by reference.

2. Description of Related Art

Recently, when forming a contact hole having a high aspect ratio, or the like, a hard mask which can be easily removed by means of ashing (i.e., an ashable hard mask) has often been used. As such an ashable hard mask, a carbon film is used, which is formed by means of plasma-enhanced chemical vapor deposition (PE-CVD).

Below, a known method of manufacturing a semiconductor device will be explained with reference to the drawings. FIGS. 7 to 12 are diagrams for showing processes of the manufacturing method in which a carbon film is used as an ashable hard mask.

First, as shown in FIG. 7, on a semiconductor substrate 201 (i.e., a wafer) in which transistors and the like (not shown) are formed, a target film 202 to be processed (here, silicon oxide film as an example) is formed, and a carbon film 203, which can function as an ashable hard mask, is further formed on the silicon oxide film 202.

Next, on the carbon film 203, an inorganic film (e.g., oxide film including silicon and oxygen) is formed as an intermediate layer 205 by means of PE-CVD. When providing optical absorbability to the intermediate layer 205 so as to prevent reflection in a lithography process, an SiOC or SiON film may be formed by further using carbon or nitrogen, or a multilayer film of such a film ad an oxide film may be formed. In addition, if handling deactivation of acid in a chemical sensitizer resist, an SiOC film or the like is formed as the intermediate layer 205. As described above, the relevant optical characteristics can be controlled to some degree, by adjusting the composition (ratio) of the intermediate layer 205.

Next, as shown in FIG. 8, a resist layer 206 is formed on the intermediate layer 205, and an opening 206a is provided in the resist layer 206 by means of exposure and development, so as to pattern the resist layer 206.

Next, as shown in FIG. 9, the intermediate layer 205 is subjected to patterning by means of known dry etching, which uses the patterned resist layer 206 as a mask.

Next, as shown in FIG. 10, the carbon film 203 is etched by using the patterned intermediate layer 205 as a mask. In this process, as the resist layer 206 is more easily etched in comparison with the carbon film 203, the resist layer 206 is removed through the etching, that is, in parallel to the etching of the carbon film 203.

Next, as shown in FIG. 11 the silicon oxide film 202 (i.e., target film to be processed) is etched by using the carbon film 203, which has been patterned by etching. In this process, the intermediate layer 205, which was used as the mask for the carbon film 203, is also removed through the etching of the silicon oxide film 202. Therefore, no additional process of removing the intermediate layer 205 is necessary.

Finally, as shown in FIG. 12, after the etching of the silicon oxide film 202 is completed, the carbon film 203 is removed by means of ashing, so that the processing of the silicon oxide film 202 is completed.

In the above-described method of manufacturing a semiconductor device, when the resist layer 206 is patterned using an exposure apparatus, it may be necessary to perform alignment using a pattern (e.g., wiring layer) which has already been formed as a ground pattern. Generally, such alignment is performed by detecting (the position of) an alignment mark by using visible light, where the alignment mark has been formed at a specific position on the relevant semiconductor substrate by using the ground pattern. Therefore, in conventional techniques, when the carbon film 203 is used as a mask, a carbon film, which is transparent in the visible range, is used so as to obtain a sufficiently high signal intensity from the alignment mark in the ground patter (see, for example, Published Japanese Translation, No. 2007-505498, of PCT International Publication, No. WO2005/034216).

However, the present inventor recognized that a transparent carbon film has a relatively high insulating capability, and thus tends to have a charged-up phenomenon. The charged-up phenomenon may occur ununiformly in the wafer plane. Such ununiform charge-up may cause an electric potential difference in the wafer plane, and the potential difference functions as the potential difference of the gate electrode of a transistor in the wafer plane. In addition, the potential difference of the gate electrode further functions as the potential difference between the relevant substrate and the gate electrode. When this potential difference increases, the gate insulating film of a transistor or the like, which has already been formed in a process prior to the process of forming the carbon film, may be subjected to dielectric breakdown.

That is, the present inventor has recognized that in the conventional method of manufacturing a semiconductor device, in which the carbon film 203 is used as an ashable hard mask, when a transparent carbon film is formed, the gate insulating film of a transistor may be subjected to dielectric breakdown, and the relevant semiconductor element may break.

### SUMMARY

The present inventor tried to form a carbon film having a high conductivity, as a carbon film which does not tend to have a charged-up phenomenon, and recognized that such a carbon film having a high conductivity has a degraded optical transmittance.

Therefore, the present inventor recognized that a desired signal intensity from the alignment mark may not be obtained by simply forming a carbon film having a high conductivity, and that it may be difficult to provide etching resistivity to such a carbon film having a high conductivity, so as to use the carbon film as an ashable hard mask.

The present invention seeks to solve one or more of the above problems, or to improve upon those problems at least in part.

In one embodiment, there is provided a method of manufacturing a semiconductor device, and the method includes forming a target film to be processed on a semiconductor substrate in which a semiconductor element has been formed; forming a hard mask on the target film; and patterning the target film. The hard mask is a multilayer film including a conductive carbon film and a transparent carbon film which are sequentially stacked on the target film.

In accordance with the present invention in which the conductive carbon film is formed, it is possible to prevent a charge-up phenomenon of the hard mask and the semiconductor substrate, and thus to prevent dielectric breakdown of semiconductor elements on the semiconductor substrate. In addition, the transparent carbon film is also formed. Therefore, even when an alignment mark is formed below the hard mask, the alignment mark can be detected via the hard mask by using visible light. Accordingly, it is possible to easily perform alignment for the exposure when patterning the hard mask. Furthermore, as the hard mask is formed by carbon films, it can be used as an ashable hard mask.

Additionally, as a multilayer mask structure including the hard mask, the intermediate layer, and the resist layer is employed, high-resolution patterning is possible. For example, a contact hole having a high aspect ratio can be easily formed.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic diagram which shows a sectional structure so as to explain one of manufacturing processes for manufacturing a semiconductor device, as a first embodiment of the present invention.

FIG. 2 is a schematic diagram which also shows a sectional structure so as to explain one of the manufacturing processes.

FIG. 3 is a schematic diagram which also shows a sectional structure so as to explain one of the manufacturing processes.

FIG. 4 is a schematic diagram which also shows a sectional structure so as to explain one of the manufacturing processes.

FIG. 5 is a schematic diagram which also shows a sectional structure so as to explain one of the manufacturing processes.

FIG. 6 is a schematic diagram which also shows a sectional structure so as to explain one of the manufacturing processes.

FIG. 7 is a schematic diagram which shows a sectional structure so as to explain one of conventional manufacturing processes for manufacturing a semiconductor device.

FIG. 8 is a schematic diagram which also shows a sectional structure so as to explain one of the conventional manufacturing processes.

FIG. 9 is a schematic diagram which also shows a sectional structure so as to explain one of the conventional manufacturing processes.

FIG. 10 is a schematic diagram which also shows a sectional structure so as to explain one of the conventional manufacturing processes.

FIG. 11 is a schematic diagram which also shows a sectional structure so as to explain one of the conventional manufacturing processes.

FIG. 12 is a schematic diagram which also shows a sectional structure so as to explain one of the conventional manufacturing processes.

### DETAILED DESCRIPTION OF PREFERRED EMBODIMENTS

The invention will now be described herein with reference to illustrative embodiments. Those skilled n the art will recognize that many alternative embodiments can be accomplished using the teachings of the present invention and that the invention is not limited to the embodiments illustrated for explanatory purposes.

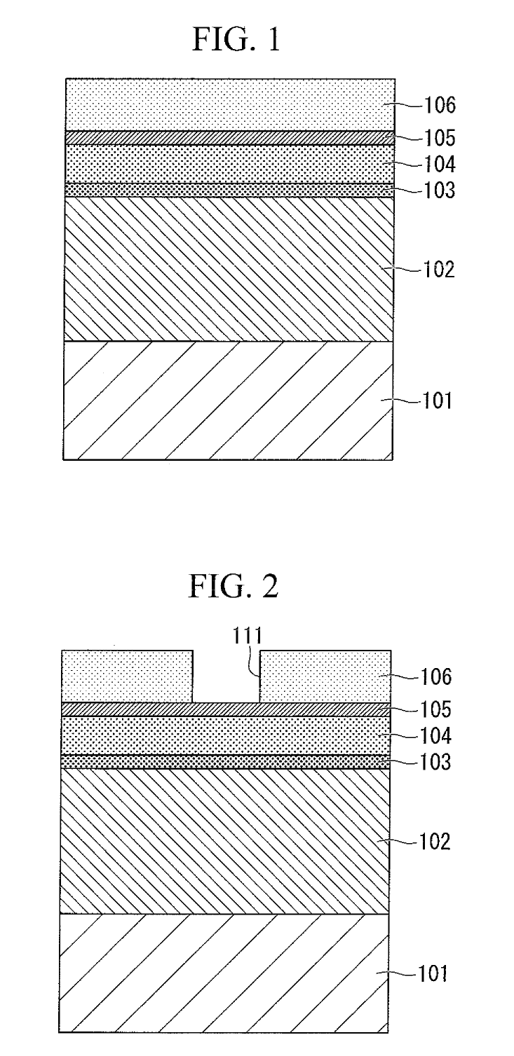

Referring now to FIGS. 1 to 6, a method of manufacturing a semiconductor device, as a first embodiment of the present invention will be explained, where FIGS. 1 to 6 are sectional views showing an example of the processes of forming a contact hole of the semiconductor device. Below, the processes will be sequentially explained.

### Formation of Target Film to be Processed

First, as shown in FIG. 1, on a semiconductor substrate 101 in which semiconductor elements (not shown) are formed, a target film 102 to be processed is formed.

The semiconductor elements may include (i) a MOS transistor, a trench-gate transistor, or a fin transistor, which has a gate insulating film and a gate electrode, (ii) a capacitor having an insulating thin film between capacitance electrodes, or the like. However, in the present invention, the semiconductor elements are not limited to the above.

The target film 102 may be a silicon oxide film (SiO₂), and is formed using a known method such as PE-CVD or thermal processing applied to a silicon substrate.

The target film 102 is not limited to a silicon oxide film (SiO₂), and may be a silicon nitride film (Si₃N₄), or a film formed by stacking these films. In addition, a film made of an insulating body, which tends to have a charge-up phenomenon, may be used as the target film 102.

### Formation of Conductive Carbon Film

Next, on the target film 102, a conductive carbon film 103 is formed, which is a constituent of a transparent multilayer film as a hard mask. The conductive carbon film 103 may be formed using a PE-CVD apparatus (e.g., “Producer SE” manufactured by Applied Materials, Inc.), under a specific high-temperature condition (called “APF (advanced patterning film)”) in which the temperature of a heater in a susceptor, on which the relevant heater is disposed, is set to 550° C.

To the formation of the conductive carbon film 103 using such a PE-CVD apparatus, the following conditions may be applied. The source gas may be a hydrocarbon compound gas such as methane (CH₄), ethane (C₂H₆), propane (C₃H₈), butane (C₄H₁₀), acetylene (C₂H₂), propylene (C₃H₆), or propyne (C₃H₈), or a mixture therebetween. Typically, methane can be used. The carrier gas may be an inert gas such as helium (He) or argon (Ar). The flow rate of the source gas may be approximately 50 to 500 sccm, and the flow rate of the carrier gas may be approximately 25 to 150 sccm. The pressure of the relevant chamber is set to 1 to 10 torr (i.e., 133 to 1333 Pa), and preferably to 3 to 7 torr (i.e., 400 to 933 Pa). The high-frequency power is set to 0.5 to 3.5 W/cm², and preferably, 2.0 to 2.5 W/cm². The low-frequency power is set to 0.5 to 2.0 W/cm², and preferably, 1.0 to 1.5 W/cm².

Additionally, it is preferable to set the film formation temperature of RE-CVD to 500° C. or higher. For the film formation temperature, the higher, the better. However, as a limitation of the film formation apparatus, the upper limit of the film formation temperature may be set to approximately 550° C. When the film formation temperature is 500° C. or higher, a film which includes a relatively large number of carbon double bonds can be formed, so that conductivity can be improved. Such a film having a relatively large number of carbon double bonds is preferable because it is conductive even though having a high optical absorbability.

In addition, it is preferable that the conductive carbon film 103 have a film thickness of 200 nm or smaller, and further preferably, 100 nm or smaller. A film having a relatively large number of carbon double bonds has a high absorption coefficient (i.e., 0.5 or higher) for the visible wavelength range (approximately 380 to 780 nm). Therefore, when the film thickness exceeds 200 nm, it is difficult to detect an alignment mark formed under a hard mask 110 (explained later), and thus it is unpreferable. In contrast, when the film thickness exceeds 200 nm or smaller, the film can transmit a sufficient amount of visible light for detecting the alignment mark, and thus it is preferable.

The resistivity of the formed conductive carbon film 103, which is measured using a four-terminal method, may be approximately 0.7 Ω·cm. Such a degree of resistivity can uniformalize the charge-up state on the surface of the relevant wafer during the formation of a transparent carbon film 104 explained later, and thus can prevent dielectric breakdown of a transistor or the like, which has already been formed. Therefore, it is preferable.

### Formation of Transparent Carbon Film

Next, on the conductive carbon film 103, the transparent carbon film 104 is formed, which is also a constituent of the transparent multilayer film as the hard mask. Similar to the conductive carbon film 103, the transparent carbon film 104 may be formed using a PE-CVD apparatus (e.g., “Producer SE” manufactured by Applied Materials, Inc.), under a specific low-temperature condition (called “APFe (advanced patterning film enhanced)”) in which the temperature of a heater in a susceptor, on which the relevant heater is disposed, is set to 350 to 400° C.

To the formation of the transparent carbon film 104 using the PE-CVD apparatus, the conditions almost similar to those applied to the conductive carbon film 103 may be applied, except for the film formation temperature.

Preferably, the film formation temperature for forming the transparent carbon film 104 is 350° C. or higher and 400° C. or lower. If the film formation temperature is lower than 350° C., no carbon film is formed, and thus it is unpreferable. In addition, if the film formation temperature exceeds 450° C., a relatively large number of carbon double bonds are included, and thus it is unpreferable. In contrast, within the above range of “350° C. or higher and 400° C. or lower”, a film which includes a relatively small number of carbon double bonds can be formed. Such a film has a low optical absorption rate for the visible wavelength range (approximately 380 to 780 nm), and thus is transparent for visible light, which is preferable.

In addition, as the transparent carbon film 104 is transparent for visible light and thus does not affect the alignment for the relevant exposure, the film thickness thereof may be set to a value which provides a sufficient resistance to the dry etching of the target film 102. In the present embodiment, the transparent carbon film 104 has a thickness of approximately 200 nm. In addition, the resistivity of the formed transparent carbon film 104 cannot be measured using a four-terminal method, which indicates that the transparent carbon film 104 is an insulating film having a very high resistivity in comparison with the conductive carbon film 103.

### Formation of Intermediate Layer

Next, an intermediate layer 105 is provided on the transparent carbon film 104. As the intermediate layer 105, an inorganic film such as a silicon oxide film (SiO₂) having a thickness of 20 to 90 nm is formed using a PE-CVD apparatus. If it is desired to provide an optical absorption capability to the intermediate layer 105 so as to prevent reflection in lithography when forming a resist layer (explained later), a carbon-incorporated silicon oxide film (i.e., SiOC film) or silicon oxynitride film (i.e., SiON film) can be formed as the intermediate layer 105 by incorporating carbon or nitrogen. In addition, a multilayer film using an SiOC or SiON film and a silicon oxide film may be used as the intermediate layer 105.

If a resist layer 106 (explained later) is a chemical sensitizer resist, and deactivation of acid should be handled, an SiOC film or the like may be formed as the intermediate layer 105.

### Formation of Resist Layer

Next, on the intermediate layer 105, a photoresist having a thickness of 200 nm is deposited, so as to form a resist layer 106. After that, as shown in FIG. 2, the resist layer 106 is subjected to exposure and development, so as to provide an opening pattern 111 in the resist layer 106. In the present embodiment, the conductive carbon film 103 is sufficiently thin so that it does not obstruct the transmission of visible light. Therefore, for the exposure of the resist layer 106, an alignment mark can be easily detected.

### Formation of Mask by Intermediate Layer

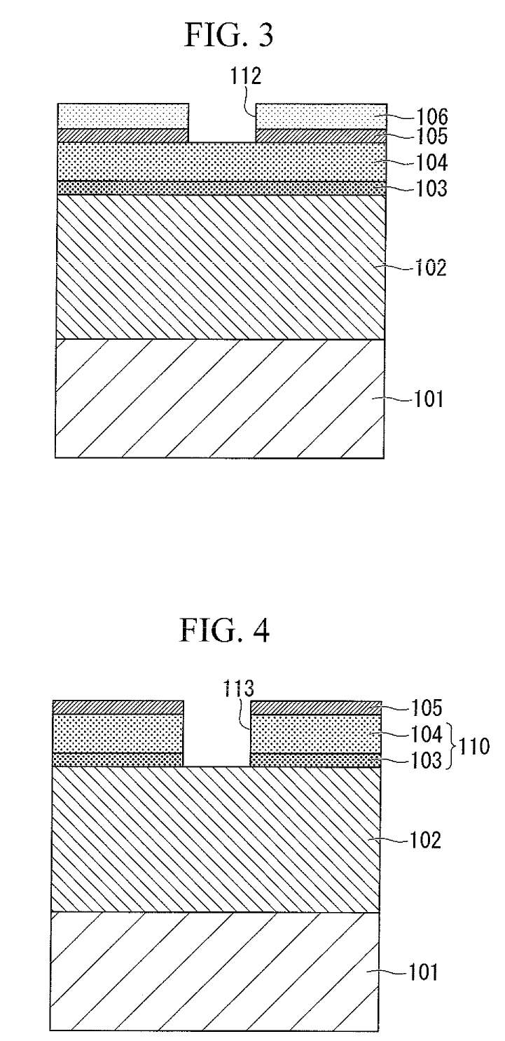

Next, as shown in FIG. 3, the intermediate layer 105 is subjected to dry etching using a known method, which uses the patterned resist layer 106 as a mask. Accordingly, an opening pattern 112 is formed, which passes through the resist layer 106 and the intermediate layer 105.

### Formation of Hard Mask

Next, as shown in FIG. 4, the transparent carbon film 104 and the conductive carbon film 103 are subjected to dry etching using a known method, which uses the patterned intermediate layer 105 as a mask. Accordingly, a hard mask 110 having an opening pattern 113 is formed. The hard mask 110 is formed by a carbon multilayer film which consists of the conductive carbon film 103 (as the first carbon film) and the transparent carbon film 104 (as the second carbon film), and can transmit visible light. In addition, the electric resistivity of the first carbon film 103 is lower than that of the second carbon film 104. Furthermore, the percentage content of carbon double bonds of the first carbon film 103 is larger than that of the second carbon film 104.

Additionally, as the resist layer 106 has a higher etching rate in comparison with the transparent carbon film 104 and the conductive carbon film 103, the resist layer 106 is removed by etching during the formation of the hard mask 110. Therefore, no additional process of removing the resist layer 106 is necessary.

### Patterning of Target Film

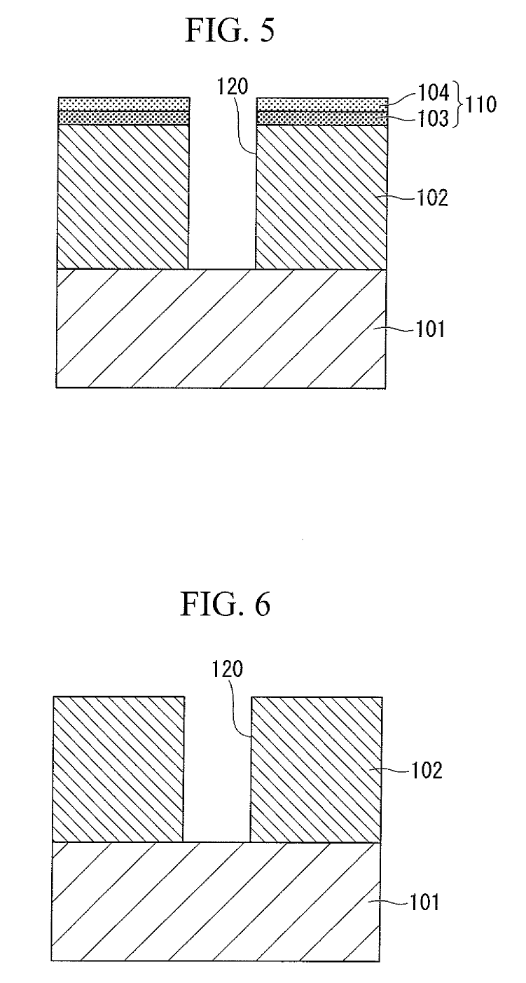

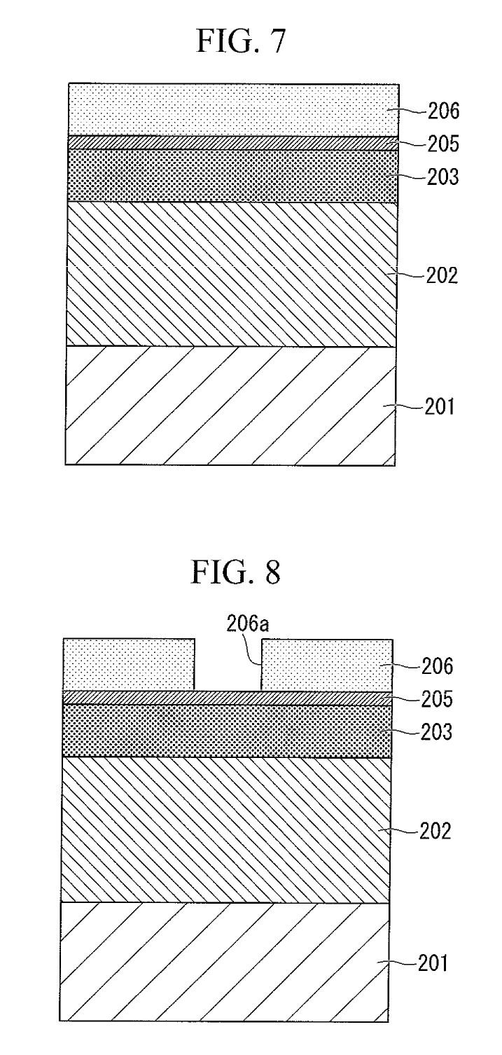

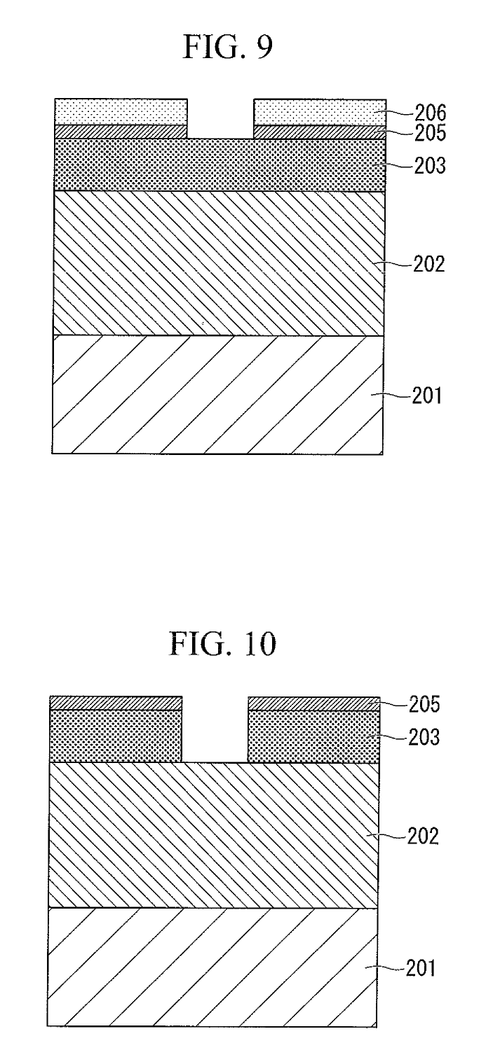

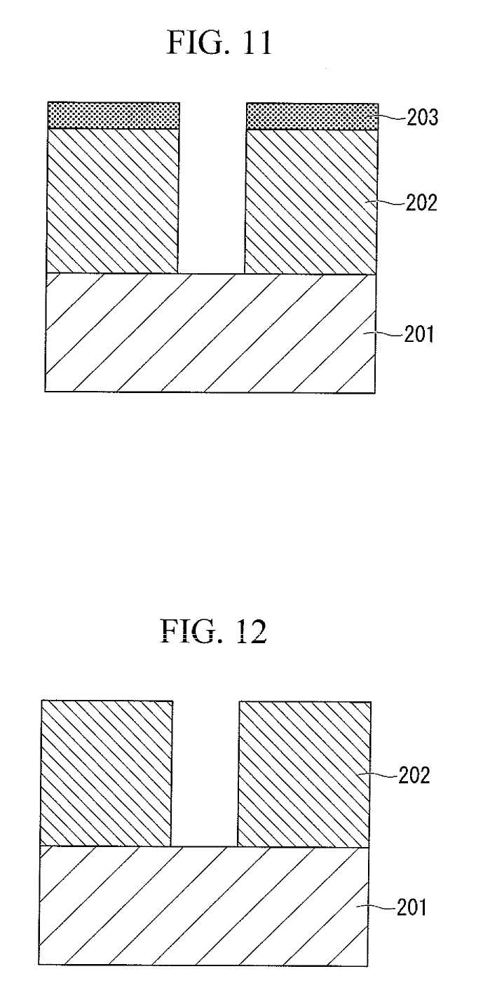

Next, as shown in FIG. 5, the target film 102 is subjected to dry etching using a known method, so that a contact hole 120 is formed.

The patterning of the target film is not always performed for forming a contact hole, but may be performed for another object, for example, for forming multilayer wiring in which an insulating film is formed on a conductive film.

In addition, the patterned intermediate layer 105, which was used as a mask for etching the hard mask 110, is removed by etching during the processing of the target film 102 (e.g., a silicon oxide film). Therefore, no additional process of removing the intermediate layer 105 is necessary.

Finally, after the etching of the target film 102 (as the subject for the relevant processing) is completed, ashing is performed, and the hard mask 110 is removed. Accordingly, the processing of the target film 102 is completed.

More specifically, ashing can be performed using a plasma ashing apparatus. Preferably, oxygen or a gas including oxygen is used as the reaction gas for ashing. In addition, a gas, which reacts to a carbon film and can generate volatile carbon oxide, carbon nitride, carbon hydride, or the like, can also be used as the reaction gas for ashing.

In ashing using oxygen plasma or the like, a silicon oxide film or the like is not etched. Therefore, the conductive carbon film 103 and the transparent carbon film 104, which form the hard mask 110, can be selectively removed without damaging the target film 102.

As described above, a film which includes a relatively large number of carbon double bonds can be formed by forming the conductive carbon film 103 at the film formation temperature of 500° C. or higher. Accordingly, A is possible to form a carbon film which has a high optical absorption rate and is also conductive.

In addition, a film which includes a relatively small number of carbon double bonds can also be formed by forming the transparent carbon film 104 at the film formation temperature of 350° C. or higher and 400° C. or lower. Accordingly, it is possible to form a carbon film which is transparent for visible light.

Also in accordance with the semiconductor device manufacturing method of the present embodiment, a charge-up phenomenon of the relevant semiconductor substrate can be prevented by forming a conductive carbon film. Therefore, it is possible to prevent dielectric breakdown of semiconductor elements on the semiconductor substrate.

That is, when forming the hard mask, the conductive carbon film 103 is first formed on the target film 102, and then the insulating transparent carbon film 104 is formed thereon. Accordingly during the formation of the transparent carbon film 104, a charge-up phenomenon of the target film 102 is prevented by means of the conductive carbon film 103. Therefore, the charge-up state on the wafer plane can be uniform, and no potential difference occurs in the wafer plane, thereby preventing dielectric breakdown of semiconductor elements on the semiconductor substrate.

In addition, the hard mask is formed by a transparent multilayer film which consists of (i) a conductive carbon film having a small film thickness by which alignment for exposure is not optically obstructed, and (ii) a transparent carbon film which is transparent for visible light. Therefore, resistance of the hard mask for dry etching is not degraded, charge-up phenomena can be prevented, and it is also possible to prevent the alignment accuracy for the exposure from being degraded.

Furthermore, as the hard mask is formed by carbon films, it can be used as an ashable hard mask.

In addition, as a multilayer mask structure including a hard mask, an intermediate layer, and a resist layer, is employed, the relevant patterning can be performed at high resolution, so that a contact hole having a high aspect ratio can be easily formed.

Below, the present invention will be explained in more detail by showing examples which were actually performed. In the examples, a contact hole was formed.

### FIRST EXAMPLE

A semiconductor device having a contact hole, as a first example, was manufactured as follows.

First, a silicon oxide film (i.e., a target film to be processed) was formed as an inter-layer insulating film on a semiconductor substrate in which a MOS transistor was formed. The MOS transistor had a gate insulating film which was a silicon oxide film having a thickness of 4 nm.

Next, a conductive carbon film was formed on the silicon oxide film provided on the semiconductor substrate. This film formation was performed using a PE-CVD apparatus (“Producer SE” manufactured by Applied Materials, Inc.), where the source gas was methane (CH₄), and a specific high-temperature condition (called “APF (advanced patterning film)”) was employed, in which the temperature of a heater in the susceptor, on which the relevant heater is disposed, was set to 550° C., so that the film thickness would be 100 nm.

The resistivity of the formed conductive carbon film, which was measured using a four-terminal method, was 0.7 Ω·cm.

Next, a transparent carbon film was formed using the PE-CVD apparatus, which had been used for forming the conductive carbon film. Here, the source gas was methane (CH₄), and a specific low-temperature condition (called “APFe (advanced patterning film enhanced)”) was employed, in which the temperature of a heater in the susceptor, on which the relevant heater is disposed, was set to 350 to 400° C., so that the film thickness would be 200 nm.

The formed carbon film was almost an insulator, and the resistivity thereof could not be measured using a four-terminal method. Additionally, the absorption coefficient thereof was approximately 0.1.

Next, on the transparent carbon film, a silicon oxide film having a thickness of 20 to 90 nm was formed as an intermediate layer by using the above-described PE-CVD apparatus. On the intermediate layer, a resist layer having a thickness of 200 nm was formed, and was subjected to exposure and development, so as to pattern the resist layer.

The intermediate layer was patterned using the formed resist layer as a mask. The transparent carbon film and the conductive carbon film were then patterned using the patterned intermediate layer, so that a hard mask was formed. Furthermore, the target film was etched using the hard mask (as a mask), so that a contact hole would be formed.

Finally, ashing was performed using an oxygen plasma apparatus, and the hard mask was removed, so that the contact hole was provided in the relevant inter-layer insulating film.

### FIRST COMPARATIVE EXAMPLE

A semiconductor device having a contact hole, as a first comparative example, was manufactured as follows.

In comparison with the above first example, the first comparative example had distinctive features in which (i) no conductive film was formed, and a transparent carbon film having a thickness of 300 nm was formed on a silicon oxide film (i.e., target film) as an inter-layer insulating film, and (ii) the target film was patterned using a hard mask which is a single layer of the transparent carbon film.

The other conditions were the same as the first example, and the contact hole was formed in the inter-layer insulating film.

### Comparative Estimation

A comparative estimation was performed between (i) the first example in which the contact hole was formed using a double-layer hard mask, and (ii) the first comparative example in which the contact hole was formed using a conventional single transparent carbon film, so as to examine the influence of the charge-up phenomena on the gate insulating film of a MOS transistor. In the comparative estimation, the yield (rate) of the MOS transistor before and after the formation of the contact hole was examined for both the first example and the first comparative example,

As the result of the examination, in the first comparative example, breakdown of the gate insulating film occurred due to a charge-up phenomenon, which degraded the yield by approximately 6%. In contrast, in the first example, dielectric breakdown of the gate insulating film due to the carbon film formation could be prevented almost completely.

In addition, for both the first example and the first comparative example, a problem, in which the alignment mark cannot be detected in the alignment of the relevant photoresist, did not occur.

It is apparent that the present invention is not limited to the above embodiments, but may be modified and changed without departing from the scope and spirit of the invention.

### INDUSTRIAL APPLICABILITY

The present invention can be generally applied to pattern formation of a carbon film as a hard mask on a target film (to be processed) which is an insulating film or the like, and thus tends to have a charge-up phenomenon.

The present invention is effectively used in technical fields such as manufacturing of a semiconductor device which has a memory device (e.g., DRAM) or a power MOS, or electronic information industry using such a semiconductor device.

What is claimed is:

1. A method of manufacturing a semiconductor device, the method comprising:
forming a target film to be processed on a semiconductor substrate in which a semiconductor element has been formed;
forming a hard mask on the target film; and
patterning the target film, wherein;
the hard mask is a multilayer film including a conductive carbon film and a transparent carbon film which are sequentially stacked on the target film.

2. The method in accordance with claim 1, wherein the formation of the hard mask includes:
sequentially stacking the conductive carbon film and the transparent carbon film on the target film on the semiconductor substrate;
sequentially stacking an intermediate layer and a resist layer on the transparent carbon film;
patterning the resist layer;
patterning the intermediate layer by using the patterned resist layer as a mask; and
patterning the conductive carbon film and the transparent carbon film by using the patterned intermediate layer as a mask.

3. The method in accordance with claim 1, wherein the conductive carbon film has a film thickness of 200 nm or smaller.

4. The method in accordance with claim 1, wherein the conductive carbon film is formed by plasma-enhanced chemical vapor deposition.

5. The method in accordance with claim 4, wherein the conductive carbon film is formed at a film formation temperature of 500° C. or higher.

6. The method in accordance with claim 1, wherein the transparent carbon film is formed by plasma-enhanced chemical vapor deposition.

7. The method in accordance with claim 6, wherein the transparent carbon film is formed at a film formation temperature of 350° C. or higher and 400° C. or lower.

8. A hard mask used when patterning a target film to be processed, which is formed on a semiconductor substrate in which a semiconductor element has been formed, wherein:
the hard mask is a carbon multilayer film which is formed by sequentially stacking a first carbon film and a second carbon film on the target film, and is able to transmit visible light; and
the first carbon film has an electric resistivity lower than that of the second carbon film.

9. The hard mask in accordance with claim 8, wherein:
the first carbon film includes a larger number of carbon double bonds in comparison with the second carbon film.
